(19) United States
(12) Patent Application Publication
(10) Pub. No.: US 2026/0343983 A1
(43) Pub. Date: Oct. 29, 2026

(54) SYSTEM AND METHODS FOR METAL BASED CONTACTS FOR TRANSISTORS

(71) Applicant: Samsung Electronics Co., Ltd., Suwon-si (KR)

(72) Inventors: Mehdi SAREMI, Danville, CA (US); Jong Chol KIM, Santa Clara, CA (US); Aravindh KUMAR, Mountain View, CA (US); Harsono SIMKA, Saratoga, CA (US)

(21) Appl. No.: 19/328,064

(22) Filed: Sep. 12, 2025

Related U.S. Application Data
(60) Provisional application No. 63/795,136, filed on Apr. 25, 2025.

(51) Int. Cl. H10D 64/01; H10D 30/00; H10D 30/01; H10D 64/62

(52) U.S. Cl. CPC H10D 64/0112; H10D 30/019; H10D 30/501; H10D 64/62

(57) ABSTRACT

A system and methods for metal-based contacts for transistors. In some embodiments, a transistor includes: a first channel; and a channel-contact structure, the channel-contact structure being at a first portion of the first channel and including: a metal interior portion, and a conductive coating, on a first surface of the metal interior portion, the conductive coating including a conductive material.

### CROSS-REFERENCE TO RELATED APPLICATION(S)

The present application claims priority to and the benefit of U.S. Provisional Application No. 63/795,136, filed Apr. 25, 2025, entitled “HIGH-PERFORMANCE MOSFET W/U-SHAPE SILICIDE”, the entire content of which is incorporated herein by reference.

### FIELD

One or more aspects of embodiments according to the present disclosure relate to circuits, and more particularly to a transistor with a metal-core source-drain.

### BACKGROUND

Transistors, such as metal-oxide semiconductor field effect transistors (MOSFETs) are widely used, including in integrated circuits. Such transistors may be combined to form logic gates in digital integrated circuits, for example. In some applications, transistors may be used to construct various other circuits, such as memory cells or registers.

It is with respect to this general technical environment that aspects of the present disclosure are related.

The above information disclosed in this Background section is only for enhancement of understanding of the background and therefore the information discussed in this Background section does not necessarily constitute prior art.

### SUMMARY

According to an embodiment of the present disclosure, there is provided a system including: a transistor, the transistor including: a first channel; and a channel-contact structure, the channel-contact structure being at a first portion of the first channel and including: a metal interior portion, and a conductive coating, on a first surface of the metal interior portion, the conductive coating including a conductive material.

In some embodiments, the conductive coating includes a silicide.

In some embodiments, the conductive material includes a doped silicide.

In some embodiments, the conductive material includes a silicide including a material selected from the group consisting of nickel, platinum, tungsten, cobalt, palladium, molybdenum, titanium, tantalum, and combinations thereof.

In some embodiments, the conductive coating is configured to transfer stress.

In some embodiments, the conductive coating includes a layer of silicide on the metal interior portion, and a first layer between the silicide and the metal interior portion.

In some embodiments, the first layer includes a material selected from the group consisting of nickel, nichrome, tantalum, hafnium, niobium, zirconium, vanadium, tungsten, tantalum nitride, indium oxide, copper silicide, titanium nitride, and combinations thereof.

In some embodiments: the transistor further includes a second channel; a conductive path from the first channel to an upper surface of the metal interior portion has a first resistance; a conductive path from the second channel to the upper surface of the metal interior portion has a second resistance; the first resistance exceeds the second resistance; and the first resistance exceeds the second resistance by at most a first set factor.

In some embodiments, the first resistance exceeds the second resistance by at most a second set factor, less than the first set factor.

According to an embodiment of the present disclosure, there is provided a method for fabricating a gate-all-around nanosheet transistor, the method including: forming a first coating layer on a stack of channels of the transistor; and forming a metal interior portion on the first coating layer.

In some embodiments, the transistor includes: a channel-contact structure, the channel-contact structure being at a first portion of a first channel of the stack of channels and including: the metal interior portion, and a conductive coating, on a first surface of the metal interior portion, the conductive coating being formed from the first coating layer and including a silicide.

In some embodiments, the method further includes forming a second coating layer on the first coating layer, wherein the conductive coating is further formed from the second coating layer.

In some embodiments, the conductive coating is in direct contact with a portion of the first channel.

In some embodiments, the silicide includes a dopant at a doping concentration of at least a threshold concentration.

In some embodiments, the silicide includes a material selected from the group consisting of nickel, platinum, tungsten, cobalt, and combinations thereof.

In some embodiments, the conductive coating includes a layer of the silicide directly on the metal interior portion.

According to an embodiment of the present disclosure, there is provided a system including: a transistor, the transistor including: a first channel; a second channel; and a channel-contact structure, the channel-contact structure being at a first portion of the channels and including: a metal interior portion; and a conductive coating, on a first surface of the metal interior portion, the conductive coating being configured to transfer stress.

In some embodiments, the conductive coating includes a silicide.

In some embodiments, the conductive coating includes a doped silicide.

In some embodiments, the conductive coating includes a silicide including a material selected from the group consisting of nickel, platinum, tungsten, cobalt, palladium, molybdenum, titanium, tantalum, and combinations thereof.

### BRIEF DESCRIPTION OF THE DRAWINGS

These and other features and advantages of the present disclosure will be appreciated and understood with reference to the specification, claims, and appended drawings wherein:

FIG. 1A is a block diagram of a digital integrated circuit, according to an embodiment of the present disclosure;

FIG. 1B is a schematic diagram of a complementary metal-oxide semiconductor (CMOS) inverter, according to an embodiment of the present disclosure;

FIG. 10 is a schematic diagram of a CMOS AND gate, according to an embodiment of the present disclosure;

FIG. 2 is a schematic cross-sectional drawing of a gate-all-around nanosheet transistor, according to an embodiment of the present disclosure;

FIG. 3A is a schematic cross-sectional drawing of a gate-all-around nanosheet transistor, according to an embodiment of the present disclosure;

FIG. 3B is a schematic cross-sectional drawing of a gate-all-around nanosheet transistor, according to an embodiment of the present disclosure;

FIG. 4A is a schematic cross-sectional drawing of an intermediate product in a method for fabricating a gate-all-around nanosheet transistor, according to an embodiment of the present disclosure;

FIG. 4B is a schematic cross-sectional drawing of an intermediate product in a method for fabricating a gate-all-around nanosheet transistor, according to an embodiment of the present disclosure;

FIG. 4C is a schematic cross-sectional drawing of an intermediate product in a method for fabricating a gate-all-around nanosheet transistor, according to an embodiment of the present disclosure;

FIG. 4D is a schematic cross-sectional drawing of an intermediate product in a method for fabricating a gate-all-around nanosheet transistor, according to an embodiment of the present disclosure;

FIG. 4E is a schematic cross-sectional drawing of an intermediate product in a method for fabricating a gate-all-around nanosheet transistor, according to an embodiment of the present disclosure;

FIG. 4F is a schematic cross-sectional drawing of an intermediate product in a method for fabricating a gate-all-around nanosheet transistor, according to an embodiment of the present disclosure;

FIG. 4G is a schematic cross-sectional drawing of an intermediate product in a method for fabricating a gate-all-around nanosheet transistor, according to an embodiment of the present disclosure;

FIG. 4H is a schematic cross-sectional drawing of an intermediate product in a method for fabricating a gate-all-around nanosheet transistor, according to an embodiment of the present disclosure;

FIG. 4I is a schematic cross-sectional drawing of an intermediate product in a method for fabricating a gate-all-around nanosheet transistor, according to an embodiment of the present disclosure;

FIG. 5A is a flow chart of a portion of a method for fabricating a gate-all-around nanosheet transistor, according to an embodiment of the present disclosure; and

FIG. 5B is a flow chart of a portion of a method for fabricating a gate-all-around nanosheet transistor, according to an embodiment of the present disclosure.

### DETAILED DESCRIPTION

The detailed description set forth below in connection with the appended drawings is intended as a description of exemplary embodiments of a transistor with a metal-core source-drain provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

Transistors (e.g., metal-oxide semiconductor field effect transistors (MOSFETs)) may be used in a variety of applications such as in digital circuits, in which they may be used to construct inverters, logic gates, and the like (as discussed in further detail below). Characteristics of transistors that may affect the performance of a circuit include power dissipation and switching speed. Both the power dissipation and the switching speed of a transistor may be affected by (i) the uniformity of the external resistance (the resistance through a source-drain to each of the channels of a transistor with a plurality of channels), (ii) the magnitude of the greatest external resistance, and (iii) the stress in the channel (which may affect the carrier mobility in the channel). In a MOSFET in which the source-drains are formed by epitaxy, the resistivity of the source-drain material may be relatively high, and the ability of the source-drain to transfer stress to the channels may be relatively low.

As such, in some embodiments, a MOSFET transistor is constructed with source-drains that have low resistance and that are capable of transferring significant stress to the channels. Such a source drain may include a metal core with a thin conductive coating. The metal core may have sufficiently high conductivity that the external resistance to each channel may be negligible compared to the resistance of the channels, and it may have mechanical characteristics (e.g., a high shear modulus, a high bulk modulus, and high internal stress) that enables it to transfer a large amount of stress to the channels. The conductive coating may be sufficiently thin to avoid significantly increasing the external resistance. The conductive coating may further be configured (e.g., it may be sufficiently thin, and have (i) a sufficiently high shear modulus, and (ii) a sufficiently high bulk modulus) to transfer stress between the metal core and the channels.

Such a source-drain may be fabricated by forming a trench at the ends of the channels, for the source-drain, depositing a layer of silicon, or a “silicon coating”, on the interior surfaces of the trench, and filing the (coated) trench with metal. An annealing step may then be used to cause the metal and the silicon coating to combine to form a silicide, which may form the conductive coating. The silicon coating may be highly doped (e.g., as a result of in-situ doping used during the fabrication of the silicon coating); this may cause the silicide to be highly doped also, avoiding the formation of, or reducing the magnitude of any Schottky barrier that may form in the source-drain. The deposition of the metal into the (coated) trench may be performed in a manner (e.g., in an argon atmosphere) that creates internal stress in the metal core, which may then be transferred to the channels.

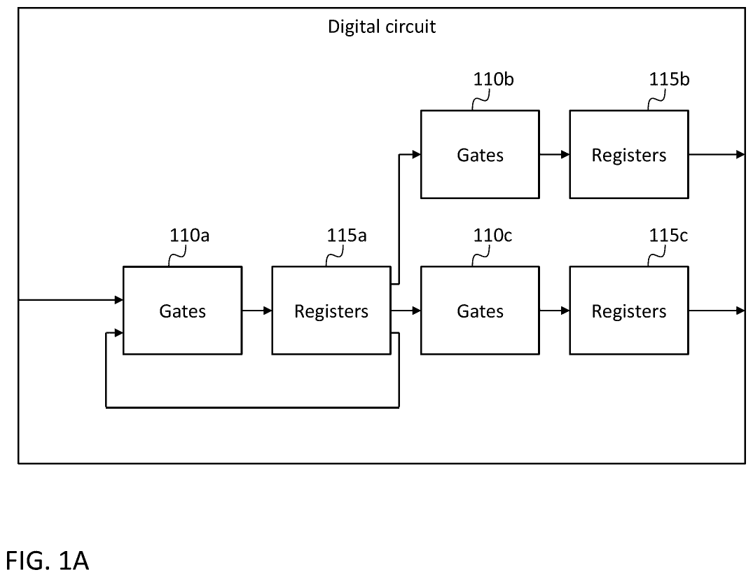

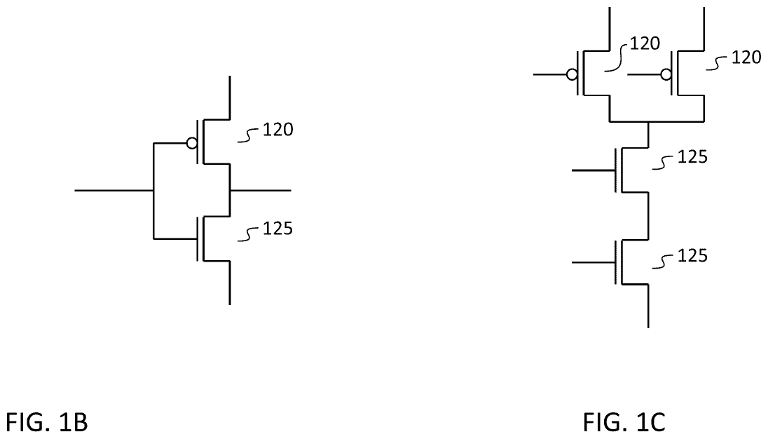

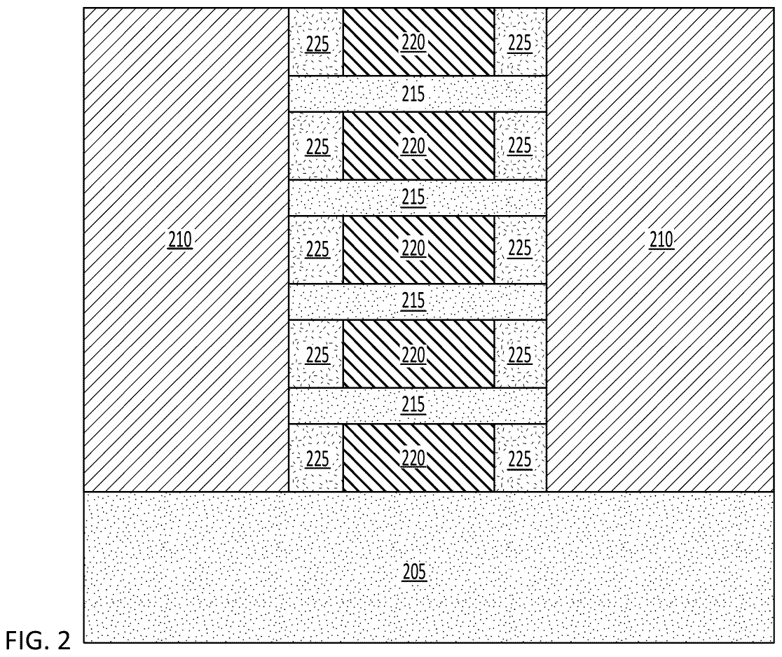

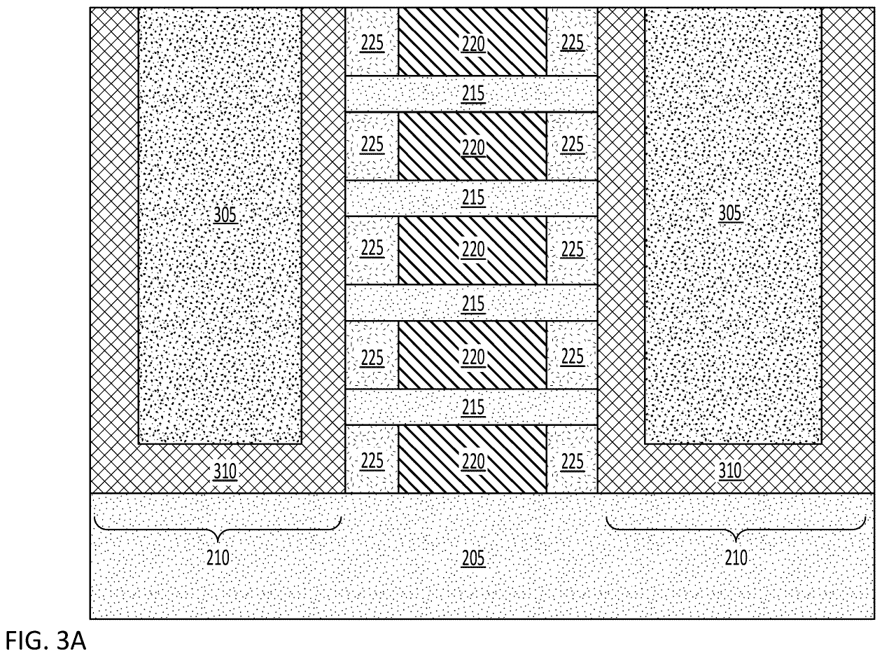

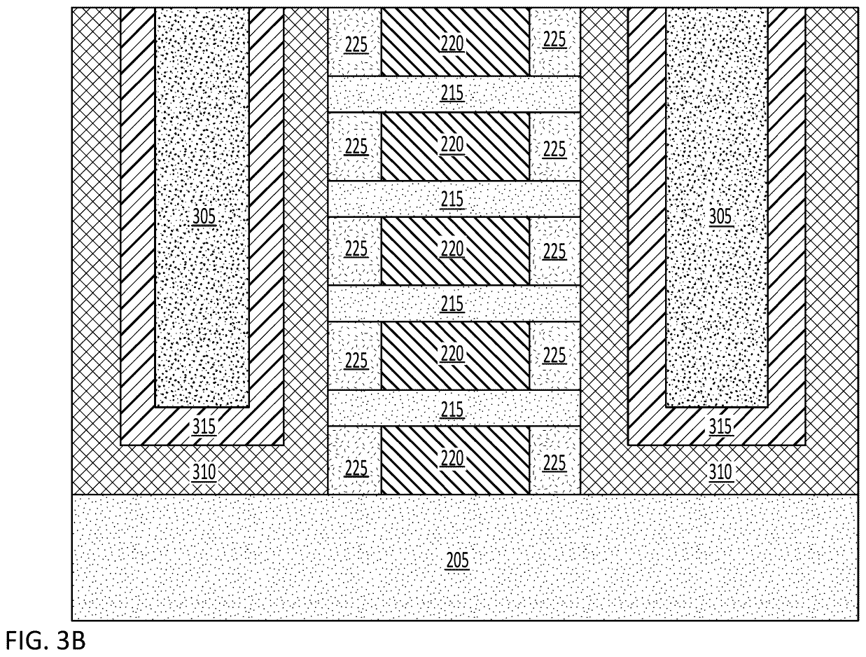

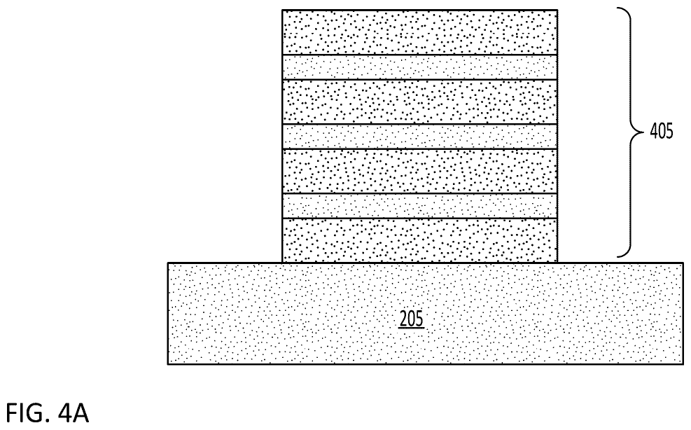

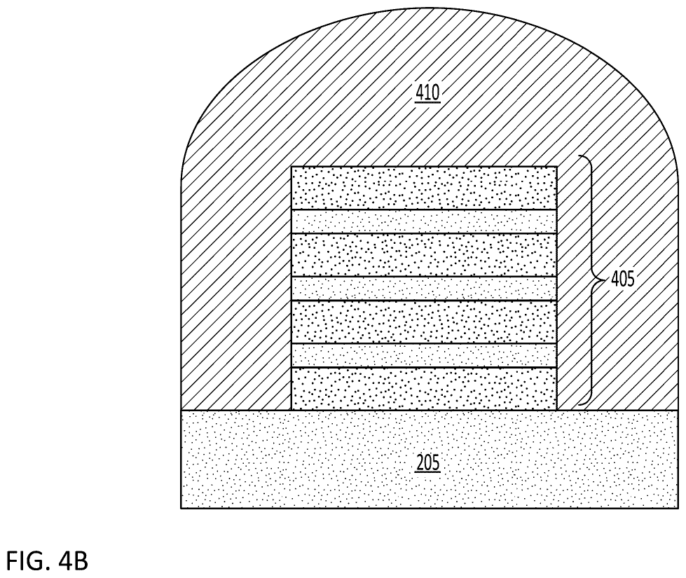

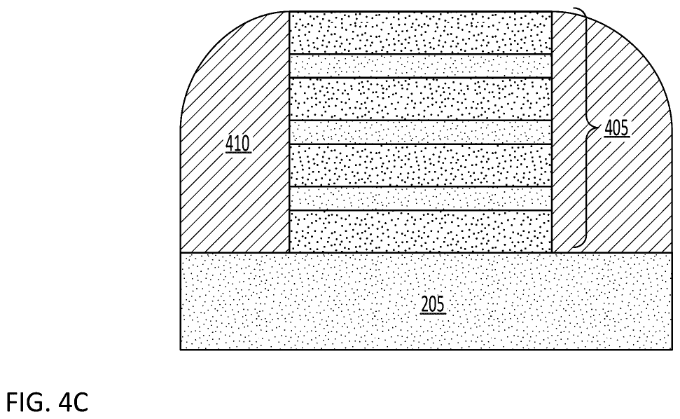

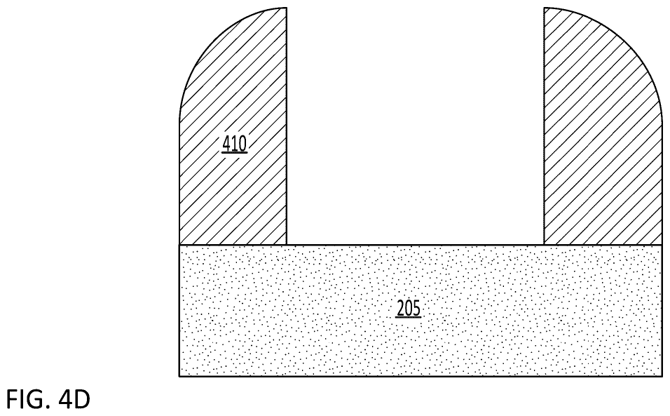

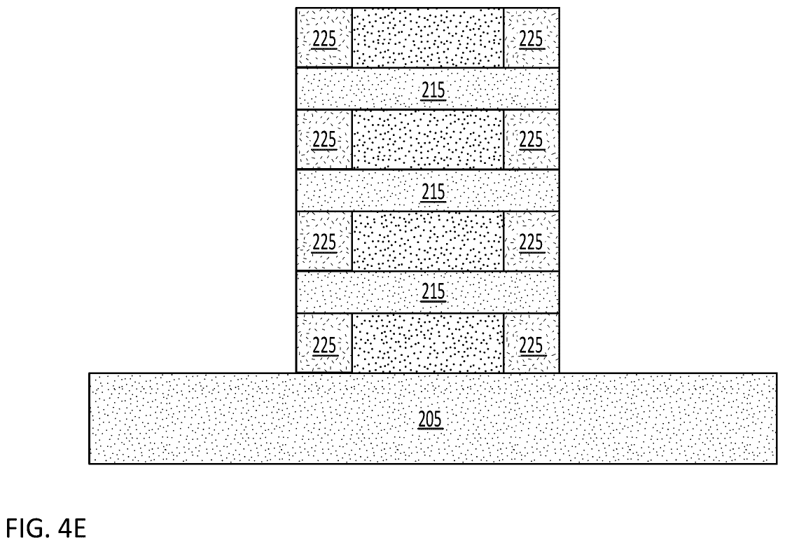

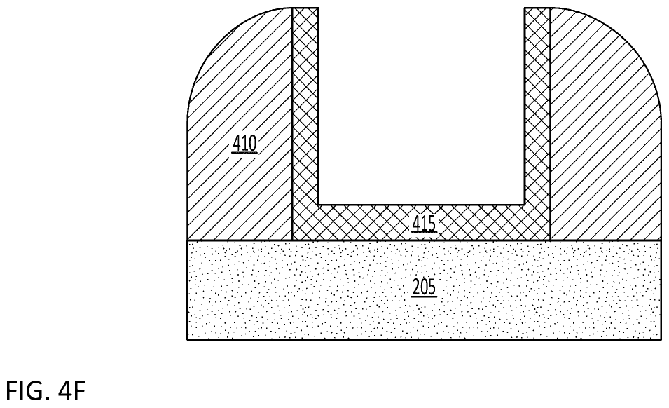

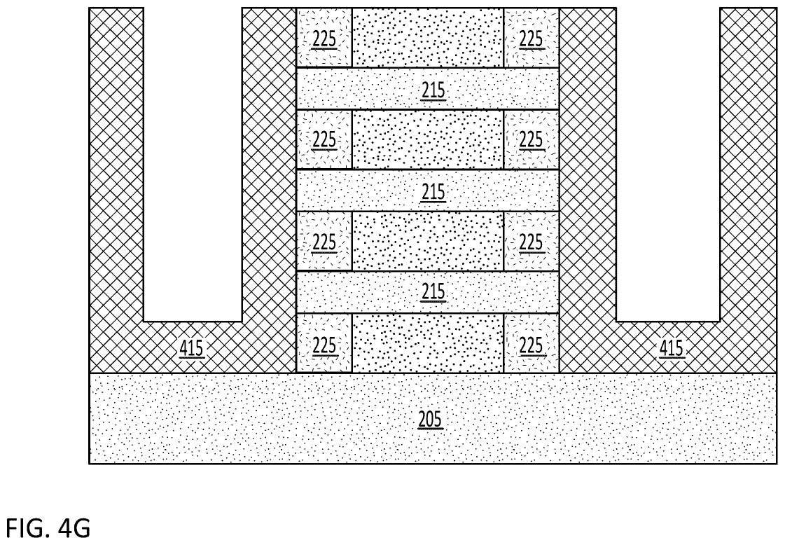

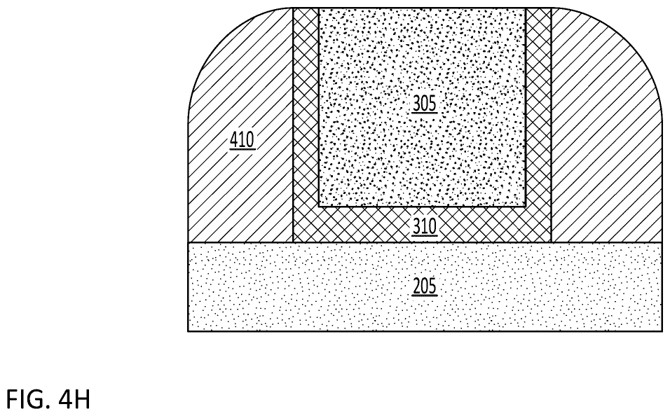

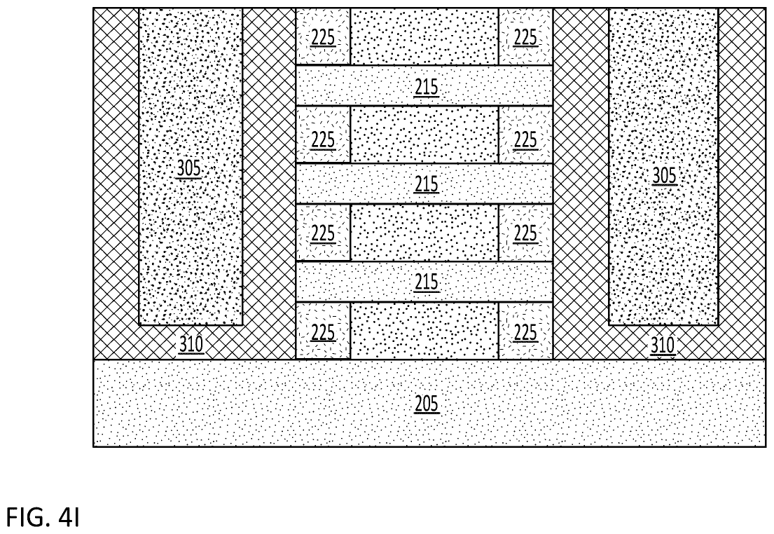

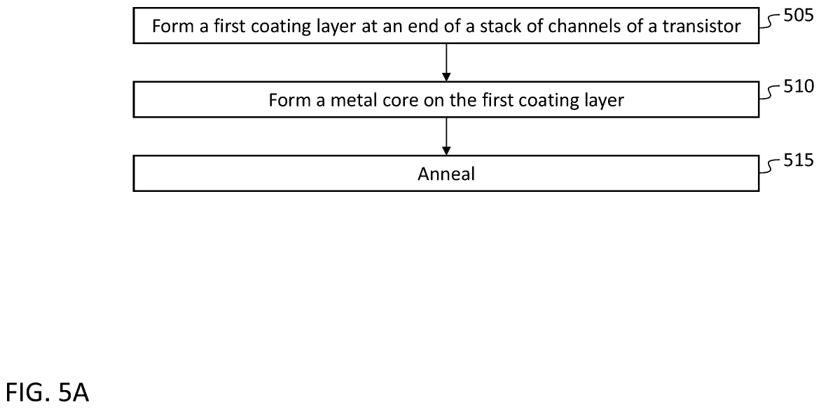

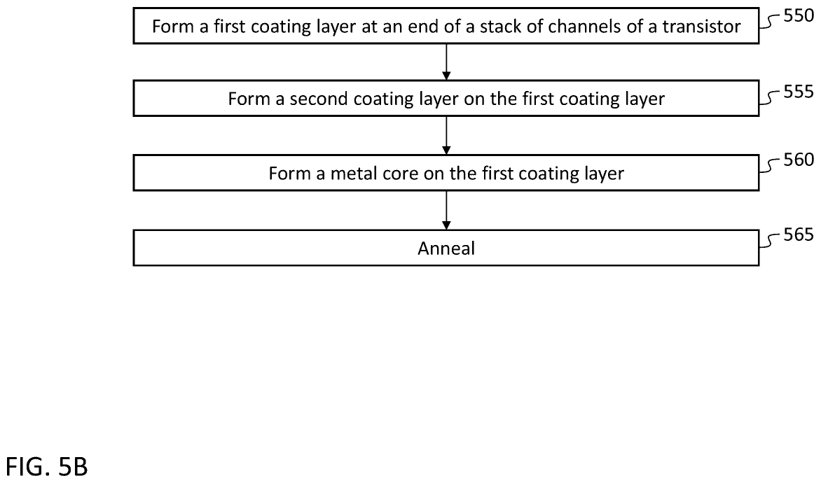

FIG. 1 shows a synchronous digital integrated circuit 105, in some embodiments. Such a synchronous digital integrated circuit 105 may be or include, for example, a central processing unit (CPU), a graphics processing unit (GPU), a neural processing unit (NPU), or any one of various other types of circuit, such as an application-specific integrated circuit (ASIC). The synchronous digital integrated circuit 105 may include one or more blocks of combinational logic (gates) 110 and one or more blocks of registers 115; for example, it may include a first block of combinational logic 110a, a second block of combinational logic 110b, and a third block of combinational logic 110c (collectively referred to as blocks of combinational logic 110), and it may include a first block of registers 115a, a second block of registers 115b, and a third block of registers 115c (collectively referred to as blocks of registers 115). As discussed in further detail below, the circuits of FIG. 1A may be constructed with transistors. The transistors used in such circuits may be MOSFET transistors according to embodiments of the present disclosure.

Each line in FIG. 1A may represent a single bit signal or a signal carrying multiple bits in parallel (e.g., a bus with a plurality of conductors each carrying a respective bit value during each clock cycle of the synchronous digital integrated circuit 105). Various interconnections may be present between the blocks of combinational logic 110 and the blocks of registers 115. For example, the outputs of a block of registers 115 may be connected to the inputs of several blocks of combinational logic 110 (as is the case with the first block of registers 115a), or the output of a block of registers 115 may be connected to the input of a block of combinational logic 110 the output of which is connected to the block of registers 115 (as is the case with the first block of registers 115a, one output of which is connected to an input of the first block of combinational logic 110a, the output of which is connected to the input of the first block of registers 115a), to form a finite state machine. The configuration of gates 110 and registers 115 is an example only and various other configurations may be implemented in a digital circuit. For example, in some embodiments, each of several blocks of registers 115 may feed a different respective input of a block of combinational logic 110.

The circuits (e.g., the blocks of combinational logic 110 and the blocks of registers 115) may include various complementary metal oxide semiconductor (CMOS) circuits, such as the CMOS inverter illustrated in FIG. 1B or the CMOS AND gate illustrated in FIG. 1C. The CMOS circuits may be constructed using transistors, e.g., p-channel metal oxide semiconductor field effect transistors 120 (which may be referred to as p-channel MOSFETs, or simply as pmos transistors) and n-channel metal oxide semiconductor field effect transistors 125 (which may be referred to as n-channel MOSFETs, or simply as nmos transistors). The circuits of FIG. 1B are, as mentioned above, constructed with transistors. The transistors used in such circuits may be MOSFET transistors according to embodiments of the present disclosure. In such circuits, the use of embodiments of the present disclosure may provide transistors with improved power dissipation (e.g., reduced power dissipation) and improved (e.g., increased) switching speed.

The pmos transistors 120 and the nmos transistors 125 may have any of several possible geometries, such as a planar geometry, a fin field effect transistor (finFET) geometry, or a gate-all-around (GAA) nanosheet geometry. The gate-all-around nanosheet geometry may have advantages of higher switching speed and lower power consumption over the planar geometry, and it may lack the fin quantization constraint of the finFET geometry.

FIG. 2 is a schematic drawing of a gate-all-around nanosheet transistor, in some embodiments. The gate-all-around nanosheet transistor is fabricated on a substrate 205 (e.g., a crystalline silicon substrate) and includes two source-drains 210 (each of which may operate as the source or the drain of the gate-all-around nanosheet transistor), a plurality of channels 215, a gate stack 220, and an insulating inner spacer 225 (which may insulate the gate stack 220 from the source-drains 210). In operation, current may flow from one source-drain 210 to the other source-drain 210 through the channels 215. The amount of current flowing flow from one source-drain 210 to the other source-drain 210 may be influenced both by the potential difference between the two source-drains 210 and the potential on the gate stack 220. As used herein, a “source-drain” (or “source-drain contact structure” or “channel-contact structure”) is a structure that may be used to form a connection to either end of the channel of a MOSFET. The transistor may be a MOSFET transistor according to embodiments of the present disclosure. The construction of the transistor according to embodiments of the present disclosure may result in a transistor with improved power dissipation and switching speed.

In some embodiments, each source-drain 210 may be composed of doped crystalline silicon (for an n-channel MOSFET), or of doped crystalline silicon-germanium (SiGe) (for a p-channel MOSFET), with a metal contact (not shown) on the top surface of the source-drain 210 or embedded in (and protruding from the top of) the source-drain 210. The fabrication process for forming such a source-drain 210 may include growing it using epitaxy, using the end surfaces of the (crystalline silicon) channels 215 and the top surface of the (crystalline silicon) substrate 205 as seed surfaces. The capacity of the source-drain 210 to transfer a (compressive or tensile) stress to the channels 215 may be degraded in such an embodiment may be significant, in part because growth begins from different spatially separated seed surfaces, and dislocation faults may tend to form where the portions of the grown material originating from different seed surfaces meet.

Further, the resistivity of the source-drains 210 may be significant and may have the effect that the resistance between the metal contact and each of the channels 215 may vary from channel to channel. For example the resistance, or “external resistance” (Rext) from one of the source-drains 210, to each of the channels, may vary from channel to channel, e.g., the external resistance of a channel 215 that is lower in the set of channels 215 may be higher than the external resistance of a channel 215 that is higher in the set of channels 215, because the length of the current path, from the metal contact through the source-drain 210 to the channel 215, may be greater for a lower channel 215 than for a higher channel 215. This variation in external resistance may result in non-uniform current flow in the channels 215 (with, e.g., the upper channels 215 carrying a greater proportion of the total current through the gate-all-around nanosheet transistor than the lower channels 215) and a corresponding degradation of performance. In some embodiments, in which a tapered metal electrode is embedded in (e.g., deposited into a tapered recess formed in) each of the source-drains 210, the external resistance of the lower channels may be reduced, but the variation in external resistance from channel to channel, with lower channels 215 having higher external resistance than higher channels 215, and the resulting loss of performance, may persist to some extent.

As such, in some embodiments, one of which is illustrated in FIG. 3A, each of the source-drains 210 incudes a metal core 305 (or “metal interior portion”) that has a substantially constant width, and that is separated from each of the channels 215 by only a thin conductive layer, or “coating”, of another material, as shown in FIG. 3A. In the embodiment of FIG. 3A, the conductive coating is a highly-doped conductive silicide coating 310. The gate-all-around nanosheet transistor of FIG. 3A includes (i) a vertical arrangement of horizontal channels 215, (ii) a gate stack 220, around the vertical arrangement of horizontal channels 215, (iii) a pair of highly-doped silicide structures 310 at the ends of the vertical arrangement of horizontal channels, (iv) a metal structure, or “metal core” 305 covered by the pair of highly-doped silicide structures 310, each of which forms a coating over the surfaces (except the top surface) of the metal core 305, and (v) an insulating inner spacer 225 between the gate stack 220 and the highly-doped silicide.

In the embodiment of FIG. 3A, the external resistance of each channel 215 may be substantially the same, and may be negligible (compared to the on-resistance of each channel 215) for all of the channels 215, because the length of the portion of the current path through the highly-doped conductive silicide coating 310 may be short (e.g., being approximately equal to the thickness of the highly-doped conductive silicide coating 310) and because the resistivity of the metal core 305 may be sufficiently low that the contribution, to the external resistance, of the portion of the current path through the metal core 305 may be negligible. As such, when the gate-all-around nanosheet transistor of the embodiment of FIG. 3A is turned on, each channel 215 may be contributing substantially equally to the current flowing through the gate-all-around nanosheet transistor.

Like the embodiment of FIG. 3A, the embodiment of FIG. 3B is a gate-all-around nanosheet transistor in which each of the source-drains 210 incudes a metal core 305 that has a substantially constant width, and that is separated from each of the channels 215 by only a thin conductive layer, or “coating”. In the embodiment of FIG. 3B, the conductive coating includes (i) a highly-doped conductive silicide coating 310, and, between the metal core 305 and the highly-doped conductive silicide coating 310, a barrier layer 315. The gate-all-around nanosheet transistor of FIG. 3B includes (like the gate-all-around nanosheet transistor of FIG. 3A) (i) a vertical arrangement of horizontal channels 215, (ii) a gate stack 220, around the vertical arrangement of horizontal channels 215, (iii) a pair of highly-doped silicide structures 310 at the ends of the vertical arrangement of horizontal channels, (iv) a metal structure, or “metal core” 305 covered by the pair of highly-doped silicide structures 310, each of which forms a coating over the surfaces (except the top surface) of the metal core 305, and (v) an insulating inner spacer 225 between the gate stack 220 and the highly-doped silicide. As mentioned above, the gate-all-around nanosheet transistor of FIG. 3B further includes a barrier layer 315 to prevent metal diffusion into the silicon horizontal channels 215.

In each of the gate-all-around nanosheet transistor of FIG. 3A and the gate-all-around nanosheet transistor of FIG. 3B, the external resistance to the horizontal channels 215 may be substantially uniform and the stress type of the metal core 305 may be either compressive or tensile. The metal of the metal core 305 may be a single material (e.g., nickel, platinum, tungsten, or cobalt) or an alloy (e.g., an alloy including one or more of nickel, platinum, tungsten, and cobalt). The metal core 305 may be deposited in layers, e.g., one layer at a time of a plurality of layers, to transfer as much stress to the channels 215 as possible, and to also exhibit low resistance. The deposition of the metal core 305 and of the highly-doped conductive silicide coating 310 may be uniform and dense.

The highly-doped conductive silicide coating 310 may be doped (e.g., with a dopant concentration (or “doping concentration”) of at least 1×10¹⁹/cm₃), both to achieve high conductivity in the highly-doped conductive silicide coating 310 and also to minimize the Schottky barrier at the interface between the highly-doped conductive silicide coating 310 and the metal core 305. In the gate-all-around nanosheet transistor of FIG. 3A, the highly-doped conductive silicide coating 310 may be sufficiently thick to act as an effective barrier against diffusion of the metal (of the metal core 305) into the silicon of the channels 215. In the gate-all-around nanosheet transistor of FIG. 3B, the barrier layer 315 may prevent diffusion of the metal (of the metal core 305) into the silicon of the channels 215, and the highly-doped conductive silicide coating 310 may therefore be thinner, in the gate-all-around nanosheet transistor of FIG. 3B, than in the gate-all-around nanosheet transistor of FIG. 3A. The barrier layer 315 may be composed of titanium nitride (TiN) or of another material suitable for use as a barrier to the diffusion of metal.

The metal cores 305 of the source-drains 210 may be fabricated (e.g., using sputtering physical vapor deposition (PVD) in argon (with the pressure of the argon being adjusted to result in suitable stress in the deposited metal core 305)) so as to apply a suitable mobility-enhancing mechanical stress to the channels. For example, in a p-channel metal oxide semiconductor field effect transistor 120, the metal cores 305 of the source-drains 210 may subject the channels 215 to a compressive stress, to enhance the hole mobility of the channels 215. In an n-channel metal oxide semiconductor field effect transistor 125, the metal cores 305 of the source-drains 210 may subject the channels 215 to a tensile stress, to enhance the electron mobility of the channels 215.

The highly-doped conductive silicide coating 310 of the gate-all-around nanosheet transistor of FIG. 3A may be capable of efficiently transferring the stress from the metal core 305 to the channels 215. For example, the highly-doped conductive silicide coating 310 may have a low compressibility as a result of (i) being thin, and (ii) having a relatively high Young's modulus (e.g., as a result of being substantially free of defects such as voids). The combination of the highly-doped conductive silicide coating 310 and the barrier layer 315 of the gate-all-around nanosheet transistor of FIG. 3B may similarly be capable of efficiently transferring the stress from the metal core 305 to the channels 215, for similar reasons.

FIGS. 4A to 4I show a method of fabricating the gate-all-around nanosheet transistor of FIG. 3A, in some embodiments. The method begins with a nanosheet stack 405 of alternating layers of silicon and silicon germanium, forming a rectangular mesa on a silicon substrate 205. In a first step of the method, a layer of an insulator 410 (e.g., silicon dioxide (or “oxide”) or silicon nitride) is deposited on the nanosheet stack 405, using an isotropic deposition process, as illustrated in FIG. 4B. In a second step of the method, an anistropic etch is employed to reduce the height of the insulator layer 410 as shown in FIG. 4C. Each of FIGS. 2-3B (and FIGS. 4E, 4G and 4I, discussed below) is a cross-sectional view taken in the Contacted Poly Pitch (CPP) direction, i.e., taken at a cutting plane that is (i) perpendicular to the surface of the substrate and (ii) parallel to a longitudinal line through the (partially fabricated or complete) gate-all-around nanosheet transistor, i.e., a line that extends through the centers of the source-drains 210. Each of FIGS. 4A-4D, 4F, and 4H is a cross-sectional view taken in the cell-height direction, i.e., taken at a cutting plane that is (i) perpendicular to the surface of the substrate and (ii) perpendicular to a longitudinal line through the (partially fabricated or complete) gate-all-around nanosheet transistor.

In a third step of the method, an anisotropic etch is used to etch two trenches, one at each end of the rectangular mesa, for forming the source-drains 210, as shown, in a cell-height view, in FIG. 4D. In a fourth step of the method, the insulating inner spacer 225 is formed, as shown in FIG. 4E, to electrically isolate source-drain regions from the gate.

In a fifth step of the method, a layer of highly-doped silicon 415 is deposited on the walls and bottom of each trench, as shown, in the cell-height direction, in FIG. 4F, and, in the CPP direction, in FIG. 4G, using an isotropic epitaxial deposition method (e.g., physical vapor deposition or chemical vapor deposition, with in-situ doping) using (i) the crystalline silicon bottom of the trench and (ii) the exposed crystalline silicon ends of the channels 215 as seed layers. The portions of the layer of highly-doped silicon 415 growing from the seed layers may be epitaxially grown to be connected together as a thin uniform layer.

In a sixth step of the method, (i) the metal core 305 is deposited in each trench, and (ii) the structure is annealed to allow the metal to diffuse into the silicon layer deposited in the fifth step, to form the highly-doped conductive silicide coating 310, as shown in the cell-height direction, in FIG. 4H, and, in the CPP direction, in FIG. 4I.

A method for forming the gate-all-around nanosheet transistor of FIG. 3B may proceed in the same manner, through the fifth step. In this method, a barrier layer may be deposited on the layer of highly-doped silicon, before depositing the metal core 305 in each trench, and, as in the method for forming the structure of FIG. 3A, the structure may be annealed to allow the metal to diffuse into the silicon layer deposited in the fifth step, to form the highly-doped conductive silicide coating 310. The annealing steps used to form the highly-doped conductive silicide coating 310 may be performed at relatively low temperature (e.g., a temperature that is significantly lower than 1000° C., e.g., a temperature of 400° C. or 300° C., or even lower). A temperature of 1000° C. or above may be required for the annealing of the source-drains 210, after epitaxy, in an embodiment such as that of FIG. 2, in which each source-drain 210 is composed of epitaxially-grown doped crystalline silicon or doped crystalline silicon-germanium.

In each method, that of fabricating the gate-all-around nanosheet transistor of FIG. 3A and that of fabricating the gate-all-around nanosheet transistor of FIG. 3B, a replacement metal gate (RMG) process may be used, after the performance of the sixth step, to replace the remaining silicon germanium portions of the nanosheet stack with a gate oxide stack and a gate metal stack. The replacement metal gate process may involve, for example, (i) the formation of a temporary, or “dummy,” gate structure, which may be composed of silicon germanium (SiGe), (ii) removal of the dummy gate, to create a void in the shape of the dummy gate, and the (iii) deposition of the metal gate in the void.

Some embodiments may provide various advantages over other structures and methods of fabrication, including (i) more uniform Rext for different channels of the gate-all-around nanosheet transistor, (ii) improved stress transfer to the channel, and (iii) the ability to avoid a high-temperature annealing step (e.g., an annealing step at a temperature of 1000° C.) during fabrication. For example, in a structure in which each source-drain 210 is composed of doped crystalline semiconductor (e.g., doped silicon or doped silicon-germanium (SiGe)), the main source of channel stress may be from the source-drain epitaxy regions; due to inner-spacer formation, the source-drain epitaxy may include dislocations resulting in stress relaxation and low performance. In some or all of the embodiments disclosed herein, the main source of channel stress is the metal core, which may be capable of effectively transferring stress to the channels 215 in spite of the presence of the inner-spacer, and therefore such an embodiment may exhibit superior performance. Further, in a structure in which each source-drain 210 is composed of doped crystalline semiconductor (e.g., doped silicon or doped silicon-germanium), the fabrication process for forming such a source-drain 210 may include growing it using epitaxy and annealing it at a temperature of approximately 1000° C. or greater. Such a high-temperature annealing step may be unnecessary in some or all of the embodiments disclosed herein; instead, in some or all of the embodiments disclosed herein an annealing step for forming silicide may be performed at a temperature of approximately 400° C. or 300° C., or even less.

FIGS. 5A and 5B are flow charts of portions of methods for fabricating gate-all-around nanosheet transistors, in some embodiments. Although FIGS. 5A and 5B illustrate various operations in such methods, embodiments according to the present disclosure are not limited thereto. For example, according to some embodiments, such methods may include additional operations or fewer operations, or the order of operations may vary (unless otherwise explicitly stated or implied) without departing from the spirit and scope of embodiments according to the present disclosure.

The method of FIG. 5A includes fabricating a gate-all-around nanosheet transistor, the fabricating including: forming, at 505, a first coating layer at an end of a stack of channels of the transistor; forming, at 510, a metal core (e.g., a metal interior portion) on the first coating layer, and performing, at 515, an annealing step. For example, as discussed above in the context of the embodiment of FIG. 3A and the steps used to fabricate this embodiment, the method may include first forming a layer of (heavily-doped) silicon in a trench and on the end face of each of a plurality of channels 215 which form portions of one wall of the trench, forming a metal core 305 in the trench, on the layer of silicon, and annealing the structure to allow the metal to diffuse into the silicon, to form silicide. The forming of the layer of silicon may be performed using epitaxy, e.g., by molecular beam epitaxy (MBE), chemical vapor deposition (CVD), or liquid phase epitaxy (LPE). The forming of the metal core may be performed, for example, using sputtering or evaporation (e.g., filament evaporation of electron-beam evaporation). The above list of processes for forming the layer of silicon and the metal core is not exhaustive, and in some embodiments other processes are used. The method of FIG. 5B includes fabricating a gate-all-around nanosheet transistor according to the embodiment of FIG. 3B. The fabricating may include: forming, at 550, a first coating layer (e.g., a layer of heavily-doped silicon) at an end of a stack of channels of the transistor; forming, at 550, a second coating layer (e.g. a barrier layer (e.g., a layer of TiN)) on the first coating layer; forming, at 560, a metal core (e.g., a metal interior portion) on the first coating layer; and performing, at 565, an annealing step. The annealing process at 565 may be used to allow the metal to diffuse into the silicon, to form silicide.

In some embodiments, a system includes a transistor, the transistor including: a first channel; and a source-drain contact structure (or “channel-contact structure”). The source-drain contact structure may be at a first portion of the first channel and may include: a metal interior portion, and a conductive coating, on a first surface of the metal interior portion, the conductive coating including a conductive material (e.g., a silicide). For example, as described above in the context of FIGS. 3A and 3B, the source-drain contact structure may include (i) a metal interior portion 305 and a conductive layer on the metal interior portion 305, the conductive surface being between the metal interior portion 305 and a first portion of each of a plurality of channels 215 of the transistor. The metal interior portion 305 may provide a high-conductivity path from a top surface of the metal interior portion 305 (through which connections to other elements (e.g., other transistors) of the integrated circuit may be made), to each of the channels 215, resulting in a substantially uniform external resistance for all of the channels 215. In some embodiments, the conductive coating is in direct contact with an end of the first channel. In some embodiments, the silicide includes a dopant at a doping concentration of at least a threshold concentration, e.g., at least a concentration of 1×10¹⁹/cm³. In some embodiments, the silicide includes a material selected from the group consisting of nickel, platinum, tungsten, cobalt, palladium, molybdenum, titanium, tantalum, and combinations thereof. In some embodiments, e.g., the embodiment of FIG. 3A, the conductive coating includes a layer of the silicide directly on the metal interior portion. In some embodiments, the conductive coating is configured to transfer stress. For example, as mentioned above, the highly-doped conductive silicide coating 310 may have a low compressibility (and be configured to transfer stress) as a result of (i) being thin, and (ii) having a relatively high Young's modulus (e.g., as a result of being substantially free of defects such as voids). In some embodiments, e.g., the embodiment of FIG. 3B, the conductive coating includes a layer of the silicide on the metal interior portion, and first layer (e.g., a barrier layer (e.g., a barrier layer of titanium nitride)) between the silicide and the metal interior portion. In some embodiments, the first layer includes a material selected from the group consisting of nickel, nichrome, tantalum, hafnium, niobium, zirconium, vanadium, tungsten, tantalum nitride, indium oxide, copper silicide, titanium nitride, and combinations thereof. In some embodiments, the transistor includes a second channel; a conductive path from the first channel to an upper surface of the metal interior portion has a first resistance; a conductive path from the second channel to the upper surface of the metal interior portion has a second resistance; the first resistance exceeds the second resistance; the first resistance exceeds the second resistance by at most a set factor (e.g., a first set factor of 2 or a second set factor of 1.2). For example, because the metal interior portion 305 provides a low-resistance vertical current path, the external resistance of the lowest one of the channels 215 may be substantially the same as (e.g., no greater than twice as great as, or no greater than 1.2 times as great as) the external resistance of the top-most one of the channels 215.

As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, when a second quantity is “within Y” of a first quantity X, it means that the second quantity is at least X-Y and the second quantity is at most X+Y. As used herein, when a second number is “within Y %” of a first number, it means that the second number is at least (1−Y/100) times the first number and the second number is at most (1+Y/100) times the first number. As used herein, the term “or” should be interpreted as “and/or”, such that, for example, “A or B” means any one of “A” or “B” or “A and B”.

The background provided in the Background section of the present disclosure section is included only to set context, and the content of this section is not admitted to be prior art. Any of the components or any combination of the components described (e.g., in any system diagrams included herein) may be used to perform one or more of the operations of any flow chart included herein. Further, (i) the operations are example operations, and may involve various additional steps not explicitly covered, and (ii) the temporal order of the operations may be varied.

As used herein, when a method (e.g., an adjustment) or a first quantity (e.g., a first variable) is referred to as being “based on” a second quantity (e.g., a second variable) it means that the second quantity is an input to the method or influences the first quantity, e.g., the second quantity may be an input (e.g., the only input, or one of several inputs) to a function that calculates the first quantity, or the first quantity may be equal to the second quantity, or the first quantity may be the same as (e.g., stored at the same location or locations in memory as) the second quantity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed herein could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

As used herein, the term “major component” refers to a component that is present in a composition, polymer, or product in an amount greater than an amount of any other single component in the composition or product. In contrast, the term “primary component” refers to a component that makes up at least 50% by weight or more of the composition, polymer, or product. As used herein, the term “major portion”, when applied to a plurality of items, means at least half of the items. As used herein, any structure or layer that is described as being “made of” or “composed of” a substance should be understood (i) in some embodiments, to contain that substance as the primary component or (ii) in some embodiments, to contain that substance as the major component.

It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present disclosure”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” or “between 1.0 and 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Similarly, a range described as “within 35% of 10” is intended to include all subranges between (and including) the recited minimum value of 6.5 (i.e., (1−35/100) times 10) and the recited maximum value of 13.5 (i.e., (1+35/100) times 10), that is, having a minimum value equal to or greater than 6.5 and a maximum value equal to or less than 13.5, such as, for example, 7.4 to 10.6. Any maximum numerical limitation recited herein is intended to include all lower numerical limitations subsumed therein and any minimum numerical limitation recited in this specification is intended to include all higher numerical limitations subsumed therein.

Some embodiments may include features of the following numbered statements.

1. A system comprising:
a transistor, the transistor comprising:
   a first channel; and
   a channel-contact structure,
the channel-contact structure being at a first portion of the first channel and comprising:
   a metal interior portion, and
   a conductive coating, on a first surface of the metal interior portion,
the conductive coating comprising a conductive material.

2. The system of statement 1, wherein the conductive coating comprises a silicide.

3. The system of statement 1 or statement 2, wherein the conductive material comprises a doped silicide.

4. The system of any one of the preceding statements, wherein the conductive material comprises a silicide comprising a material selected from the group consisting of nickel, platinum, tungsten, cobalt, palladium, molybdenum, titanium, tantalum, and combinations thereof.

5. The system of any one of the preceding statements, wherein the conductive coating is configured to transfer stress.

6. The system of any one of the preceding statements, wherein the conductive coating comprises a layer of silicide on the metal interior portion, and a first layer between the silicide and the metal interior portion.

7. The system of statement 6, wherein the first layer comprises a material selected from the group consisting of nickel, nichrome, tantalum, hafnium, niobium, zirconium, vanadium, tungsten, tantalum nitride, indium oxide, copper silicide, titanium nitride, and combinations thereof.

8. The system of any one of the preceding statements, wherein:
the transistor further comprises a second channel;
a conductive path from the first channel to an upper surface of the metal interior portion has a first resistance;
a conductive path from the second channel to the upper surface of the metal interior portion has a second resistance;
the first resistance exceeds the second resistance; and
the first resistance exceeds the second resistance by at most a first set factor.

9. The system of statement 8, wherein the first resistance exceeds the second resistance by at most a second set factor, less than the first set factor.

10. A method for fabricating a gate-all-around nanosheet transistor, the method comprising:
forming a first coating layer on a stack of channels of the transistor; and
forming a metal interior portion on the first coating layer.

11. The method of statement 10, wherein the transistor comprises:
a channel-contact structure,
the channel-contact structure being at a first portion of a first channel of the stack of channels and comprising:
the metal interior portion, and
a conductive coating, on a first surface of the metal interior portion,
the conductive coating being formed from the first coating layer and comprising a silicide.

12. The method of statement 11, further comprising forming a second coating layer on the first coating layer, wherein the conductive coating is further formed from the second coating layer.

13. The method of any one of the preceding statements, wherein the conductive coating is in direct contact with a portion of the first channel.

14. The method of any one of the preceding statements, wherein the silicide includes a dopant at a doping concentration of at least a threshold concentration.

15. The method of any one of the preceding statements, wherein the silicide comprises a material selected from the group consisting of nickel, platinum, tungsten, cobalt, and combinations thereof.

16. The method of any one of the preceding statements, wherein the conductive coating comprises a layer of the silicide directly on the metal interior portion.

17. A system comprising:
a transistor, the transistor comprising:
   a first channel;
   a second channel; and
   a channel-contact structure,
the channel-contact structure being at a first portion of the channels and comprising:
   a metal interior portion; and
   a conductive coating, on a first surface of the metal interior portion,
the conductive coating being configured to transfer stress.

18. The system of statement 17, wherein the conductive coating comprises a silicide.

19. The system of statement 17 or statement 18, wherein the conductive coating comprises a doped silicide.

20. The system of statement 17, wherein the conductive coating comprises a silicide comprising a material selected from the group consisting of nickel, platinum, tungsten, cobalt, palladium, molybdenum, titanium, tantalum, and combinations thereof.

Although exemplary embodiments of a transistor with a metal-core source-drain have been specifically described and illustrated herein, many modifications and variations will be apparent to those skilled in the art. Accordingly, it is to be understood that a transistor with a metal-core source-drain constructed according to principles of this disclosure may be embodied other than as specifically described herein. The invention is also defined in the following claims, and equivalents thereof.

What is claimed is:

1. A system comprising:
a transistor, the transistor comprising:
a first channel; and
a channel-contact structure,
the channel-contact structure being at a first portion of the first channel and comprising:
a metal interior portion, and
a conductive coating, on a first surface of the metal interior portion,
the conductive coating comprising a conductive material.

2. The system of claim 1, wherein the conductive coating comprises a silicide.

3. The system of claim 1, wherein the conductive material comprises a doped silicide.

4. The system of claim 1, wherein the conductive material comprises a silicide comprising a material selected from the group consisting of nickel, platinum, tungsten, cobalt, palladium, molybdenum, titanium, tantalum, and combinations thereof.

5. The system of claim 1, wherein the conductive coating is configured to transfer stress.

6. The system of claim 1, wherein the conductive coating comprises a layer of silicide on the metal interior portion, and a first layer between the silicide and the metal interior portion.

7. The system of claim 6, wherein the first layer comprises a material selected from the group consisting of nickel, nichrome, tantalum, hafnium, niobium, zirconium, vanadium, tungsten, tantalum nitride, indium oxide, copper silicide, titanium nitride, and combinations thereof.

8. The system of claim 1, wherein:
the transistor further comprises a second channel;
a conductive path from the first channel to an upper surface of the metal interior portion has a first resistance;
a conductive path from the second channel to the upper surface of the metal interior portion has a second resistance;
the first resistance exceeds the second resistance; and
the first resistance exceeds the second resistance by at most a first set factor.

9. The system of claim 8, wherein the first resistance exceeds the second resistance by at most a second set factor, less than the first set factor.

10. A method for fabricating a gate-all-around nanosheet transistor, the method comprising:
forming a first coating layer on a stack of channels of the transistor; and
forming a metal interior portion on the first coating layer.

11. The method of claim 10, wherein the transistor comprises:
a channel-contact structure,
the channel-contact structure being at a first portion of a first channel of the stack of channels and comprising:
the metal interior portion, and
a conductive coating, on a first surface of the metal interior portion,
the conductive coating being formed from the first coating layer and comprising a silicide.

12. The method of claim 11, further comprising forming a second coating layer on the first coating layer, wherein the conductive coating is further formed from the second coating layer.

13. The method of claim 11, wherein the conductive coating is in direct contact with a portion of the first channel.

14. The method of claim 11, wherein the silicide includes a dopant at a doping concentration of at least a threshold concentration.

15. The method of claim 11, wherein the silicide comprises a material selected from the group consisting of nickel, platinum, tungsten, cobalt, and combinations thereof.

16. The method of claim 11, wherein the conductive coating comprises a layer of the silicide directly on the metal interior portion.

17. A system comprising:
a transistor, the transistor comprising:
a first channel;
a second channel; and
a channel-contact structure,
the channel-contact structure being at a first portion of the channels and comprising:
a metal interior portion; and
a conductive coating, on a first surface of the metal interior portion,
the conductive coating being configured to transfer stress.

18. The system of claim 17, wherein the conductive coating comprises a silicide.

19. The system of claim 17, wherein the conductive coating comprises a doped silicide.

20. The system of claim 17, wherein the conductive coating comprises a silicide comprising a material selected from the group consisting of nickel, platinum, tungsten, cobalt, palladium, molybdenum, titanium, tantalum, and combinations thereof.
